(19) United States
(12) Patent Application Publication
(10) Pub. No.: US 2004/0145026 A1
(43) Pub. Date: Jul. 29, 2004

(54) Photonic transmitter

(76) Inventors: Chi-Kuang Sun, Taipei (TW); Jin-Wei Shi, Taipei (TW)

Correspondence Address: SUPREME PATENT SERVICES, POST OFFICE BOX 2339, SARATOGA, CA, 95070, US

(21) Appl. No.: 10/354,362

(22) Filed: Jan. 29, 2003

(51) Int. Cl. H01L 31/00

(52) U.S. Cl. 257/459

(57) ABSTRACT

A photonic transmitter includes a semi-insulating substrate and an edge-coupled traveling wave photodetector formed on the substrate. The edge-coupled traveling wave photodetector includes an active layer formed on the semi-insulating substrate, which is made by implanting impurity atoms in regular temperature grown III-V semiconductor materials for absorption of photons of an incident light and broadening electrical bandwidth thereof. An electrode structure is formed on the active layer, comprised of three metal strips for generating and conveying electromagnetic waves. A planar antenna is coupled to the electrode structure for transmitting the electromagnetic waves. The antenna and the photodetector are monolithically integrated on the substrate to form a unitary device

### FIELD OF THE INVENTION

The present invention relates generally to a photonic transmitter, and in particular to a high efficiency photonic transmitter comprised of an edge-coupled photodetector and a planar antenna integrated together as a single unit.

### BACKGROUND OF THE INVENTION

With the progress of technology and the increased applications of microwaves, signal interference is often encountered in the applications of electromagnetic waves within the range of microwave. Thus, millimeter or sub-millimeter wave region of the electromagnetic spectrum is becoming increasingly important for commercial and military applications. This is due to the advantages that the millimeter or sub-millimeter wave region of the electromagnetic spectrum is relatively less crowded and that image resolution can be enhanced with the high frequency of the millimeter or sub-millimeter waves. In addition, the use of millimeter or sub-millimeter waves allows the use of smaller antenna size, as well as increasing the amount and speed of data transmittal.

Structurally, a photonic transmitter is comprised of a photodetector for receiving a laser beam from a laser source and converts the received laser beam into high frequency electromagnetic waves, which is then transmitted through an antenna for a variety of applications, such as molecular imaging, atmospheric monitoring and astronomical research and range finding.

Conventionally, the photodetector of the photonic transmitter is made of III-V semiconductors, such as GaAs, which receives the laser beam from a laser source positioned above the photodetector. This is the so-called vertical illumination. The conventional device suffers narrow bandwidth and poor conversion efficiency due to adverse factors, such as RC time constant, carrier life time and carrier drift time. To overcome the insufficiencies, low-temperature grown GaAs (LTG-GaAs) was adapted to shorten the carrier lift time and carrier drift time. An example is shown in U.S. Pat. No. 4,952,527. Although the LTG-GaAs based photodetector broadens the bandwidth, it still has low conversion efficiency. In addition, e-beam lithography must be employed in making the photodetector.

U.S. Pat. Nos. 6,418,248 and 5,572,014 disclose edge-coupled photodetectors, such as traveling wave photodetector (TWPD) and waveguide photodetector (WGPD). The LTG-GaAs based TWPD that has a p-i-n (p⁺-intrinsic-n⁺) structure can provide a bandwidth of 520 GHz and a quantum efficiency of 8%. However, the bandwidth of this known device severely deteriorates when an attempt to increase the saturation current by elongating the device is made.

Further, the high conversion rate of the LTG-GaAs photodetector is achieved by defects present in the semiconductor materials. However, regular temperature grown III-V semiconductors do not contain a sufficient amount of such defects in order to achieve such a conversion rate. On the other hand, the LTG-GaAs does not allow for monolithic integration with other semiconductor materials. This restricts its applications.

### SUMMARY OF THE INVENTION

Thus, an object of the present invention is to provide a photonic transmitter having a broad bandwidth and high conversion efficiency.

Another object of the present invention is to provide a photonic transmitter having a p-i-n structure where “i” represents a regular temperature grown, impurity-implanted III-V semiconductor which allows the photonic transmitter to be formed on the same substrate without employing re-growth techniques.

A further object of the present invention is to provide an in-plane millimeter or sub-millimeter wave generator.

To achieve the above object, in accordance with the present invention, there is provided a photonic transmitter comprising a semi-insulating substrate and an edge-coupled traveling wave photodetector formed on the substrate. The edge-coupled traveling wave photodetector comprises an active layer formed on the semi-insulating substrate, which is made by implanting impurity atoms in regular temperature grown III-V semiconductor materials for absorption of photons of an incident light and increasing electrical bandwidth thereof. An electrode structure is formed on the active layer, comprised of three metal strips for generating and guiding electromagnetic waves. A planar antenna is coupled to the electrode structure for transmitting the electromagnetic waves. The antenna and the photodetector are monolithically integrated on the substrate to form a unitary device.

### BRIEF DESCRIPTION OF THE DRAWINGS

The present invention will be apparent to those skilled in the art by reading the following description of preferred embodiments thereof, with reference to the attached drawings, in which:

FIG. 1 is a top view of a photonic transmitter constructed in accordance with the present invention;

FIG. 2 is a top view of a photodetector of the photonic transmitter of the present invention;

FIG. 3 is a side elevational view of the photodetector of the present invention;

FIG. 4 is a side elevational view of a photodetector employed in the photonic transmitter of the present invention;

FIG. 5 is a plot of the relative transmission power of the photonic transmitter at different frequencies;

FIG. 6 is a perspective view of an integrated photonic transmitter in accordance with the present invention;

FIG. 7 is a top view of a first application of the photonic transmitter of the present invention;

FIG. 8 is a top view of a second application of the photonic transmitter of the present invention;

FIG. 9 is a top view of a third application of the photonic transmitter of the present invention; and

FIG. 10 is a top view of a fourth application of the photonic transmitter of the present invention.

### DETAILED DESCRIPTION OF THE INVENTION

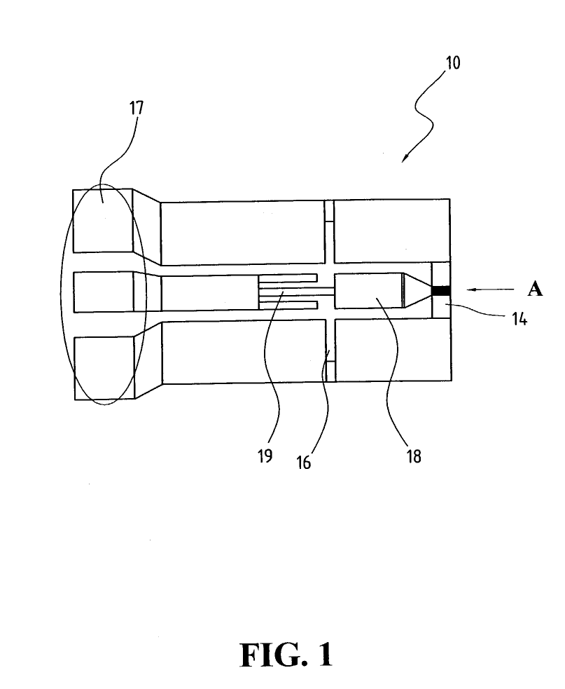

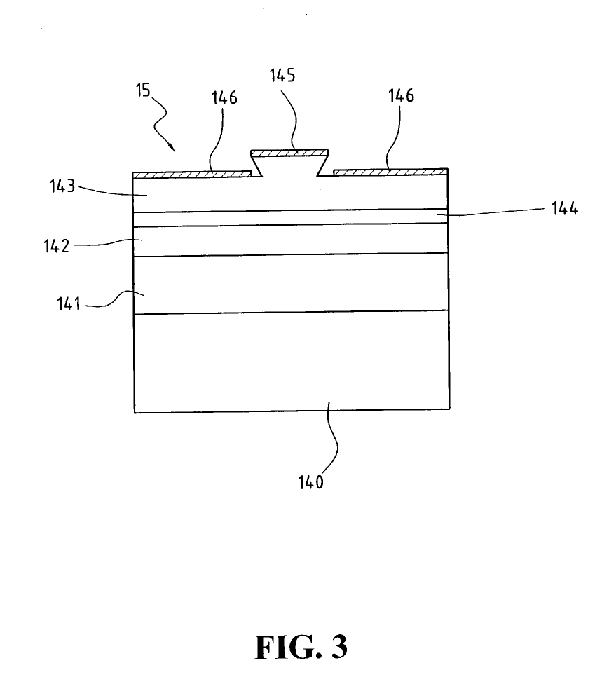

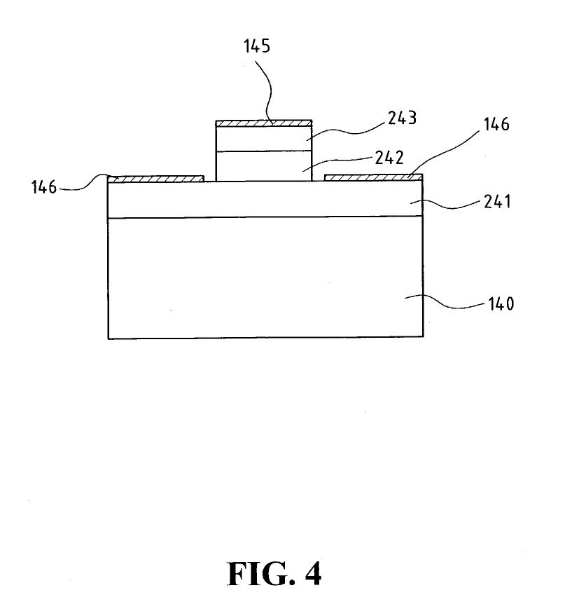

With reference to the drawings and in particular to FIG. 1, a photonic transmitter constructed in accordance with the present invention, generally designated with reference numeral 10, comprises a photodetector 14 and a printed circuit antenna or a planar antenna 16. The photodetector 14 receives light from an external light source, such as a laser, as indicated by arrow A, and converts the light into electromagnetic waves, which are then transmitted through the antenna 16. In the embodiment illustrated, the photodetector 14 is a traveling wave photodetector (TWPD) having a MSM (metal-semiconductor-metal) structure (FIG. 3) or a p-i-n (p⁺-intrinsic-n⁺) structure (FIG. 4).

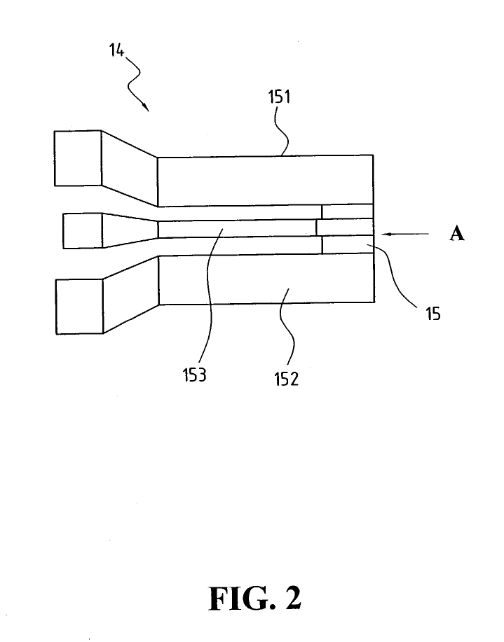

Also referring to FIG. 2, the photodetector 14 comprises a photo-absorption region 15 of which a side elevational view is shown in FIG. 3 (for MSM structure) or FIG. 4 (for p-i-n structure). The photo-absorption region 15 of the photodetector having MSM structure, as shown in FIG. 3, comprises a semi-insulating substrate 140, made of III-V semiconductor materials, such as GaAs, GaSb and InP, an optical isolation layer 141 and a cladding layer 142 sequentially stacked over the substrate 140. An active layer 143 is formed on the cladding layer 142 with a diffusion barrier layer 144 therebetween. The active layer 143 is made of low temperature grown semiconductor, such as LTG GaAs or other low temperature grown semiconductors, including LTG InxGa1-xAs, LTG GaAsySb1-y, LTG InAs, LTG InxGa1-xAsyN1-y, but not limited thereto. Alternatively, the active layer 143 can be made of regular temperature grown semiconductor implanted with proton or positive ions, such as O⁺, Ni⁺, As⁴⁺, As⁺, N, H, F, Ar, P, B, Ni, Mn, Co and Nd for shortening the carrier lift time thereof. The diffusion barrier layer 144 is preferably made of AlAs.

The optical isolation layer 141 and the cladding layer 142 are both made of AlxGa1-xAs based material having a basic composition of AlxGa1-xAs. In the embodiment illustrated, the composition of the optical isolation layer 141 is Al_{0.5}Ga_{0.5}As having a thickness of 3 μm for separating the active layer 143 from the substrate 140, while that of the cladding layer 142 is Al_{0.35}Ga_{0.65}As having a thickness of 1 μm and serving as optical wave guiding. The active layer 143 functions for absorption of the photons of the external light source and conversion into millimeter or sub-millimeter electromagnetic waves. The diffusion barrier layer 144 has a thickness of about 100 Å for preventing As atoms from out-diffusion during annealing.

A coplanar waveguide (CPW) is formed on the active layer 143 for supporting a photo-excited microwave guiding mode, which comprises an electrode structure comprised of three metal strips, a central strip 145 and two side strips 146, wherein the side strips 146 are grounding lines and are spaced from the central strip 145. By means of the MSM structure formed with the metal strips 145, 146 and the active layer 143, the incident light from the external light source is effectively converted into electromagnetic waves.

The coplanar waveguide can be made with any suitable semiconductor manufacturing process, such as self-aligned process, wherein an undercut is formed in the active layer 143 under the central strip 145 for spacing the side strips 146 from the central strip 145. The space between the side strips 146 and the central strip 145 can be as small as 200-300 nm. Thus, no e-beam lithography is required. Certainly, if desired, the e-beam lithography can be employed to form the coplanar waveguide. The advantages of reducing the gap size between the strips 145, 146 is shortening the carrier drift time, increasing electric field strength and enhancing internal quantum efficiency. In addition, in ultrahigh frequency applications, minimizing the gap reduces loss of microwave radiation.

The active layer 143 and the cladding layer 142 are respectively made of GaAs and AlxGa1-xAs which can be formed by semiconductor manufacturing processes, making the dominant propagation microwave mode “quasi-TEM mode”, instead of “slow wave mode” in the previously known p-i-n based TWPD structure. The characteristics of low loss and high velocity in the quasi-TEM microwave mode ensure low bandwidth degradation for long absorption length devices. In an embodiment of the present invention, a 0.8 ps impulse response FWHM (Full-Width-Half-Maximum) and a 570 GHz transformed electrical bandwidth are observed at 800 nm wavelength regime.

In addition to the photo-absorption region 15, the photodetector 14 also comprises CPW lines 151, 152, 153 respectively connected with the metal strips 146, 145 of the photo-absorption region 1S for transmission of millimeter or sub-millimeter electromagnetic waves.

Referring back to FIG. 1, the printed circuit antenna 16 is a CPW fed slot antenna that is coupled to the photodetector 14 via an impedance matching section 18 providing a proper match of impedance between the photodetector 14 and the antenna 16. The antenna 16 further comprises an RF isolation bias tee 19 for preventing high frequency alternate signal that resonates with the antenna from entering a DC probe pad 17. It is apparent that the impedance matching section 18 is preferably made in planar form for integration with the photodetector 15 and the antenna 16.

FIG. 4 shows a p-i-n structure, which comprises a p-layer 241, an i-layer 242 and an n-layer 243 sequentially grown on the semi-insulating substrate 140 in regular temperatures. The p-layer 241 and the n-layer 243 are respectively made of p-type AlxGa1-xAs and n-type AlxGa1-xAs, while the i-layer 242 is made of GaAs. Other materials, such as InAlAs, InP and InxGa1-xAsyP1-y, can be used to make the p-layer 241 and the n-layer 243, while the i-layer 242 can also be made of InxGa1-xAs. Defects are formed in the i-layer 242 by implanting impurity atoms for cooperation with the p-layer 241 and the n-layer 243 above and below the i-layer 242 to efficiently convert the incident light into electromagnetic waves. Metals strips 146, 145 are formed on the p-layer 241 and the n-layer 243 to transmit the electromagnetic waves. It is noted that the regular temperature grown GaAs allows the p-i-n structure to be integrated with semiconductor devices other than the photodetector 14 without crystal re-growth.

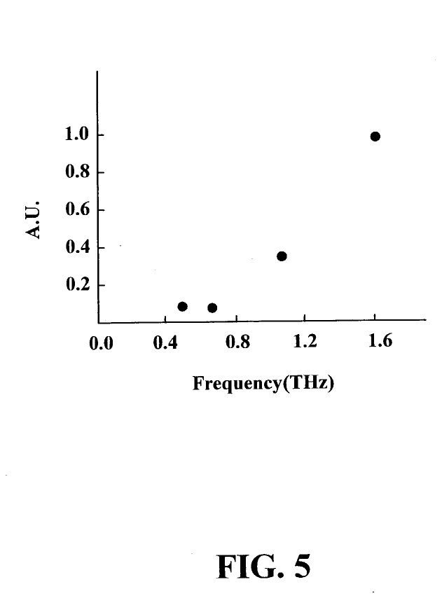

FIG. 5 shows the relative variation of the power transmitted by the photonic transmitter 10 of the present invention in different working frequencies. It is noted that the photonic transmitter 10 of the present invention has the largest power output in 1.6 THz.

As mentioned previously, by growing every portion of the photodetector 14 in regular temperatures and by utilizing a CPW fed slot antenna as the antenna 16, the present invention provides an important feature of monolithic integration of the antenna 16 and the photodetector 14 as a unitary device.

Further, the substrate 140 of the photo-absorption region 15 of the photodetector 14 can be replaced by a low dielectric constant substrate, made of for example glass, quartz, plastic polymer and silicon carbide (SiC) that allows for penetration of millimeter or sub-millimeter waves without severe interference therewith. Thus, transmission of electromagnetic waves into space is enhanced without using Si lens.

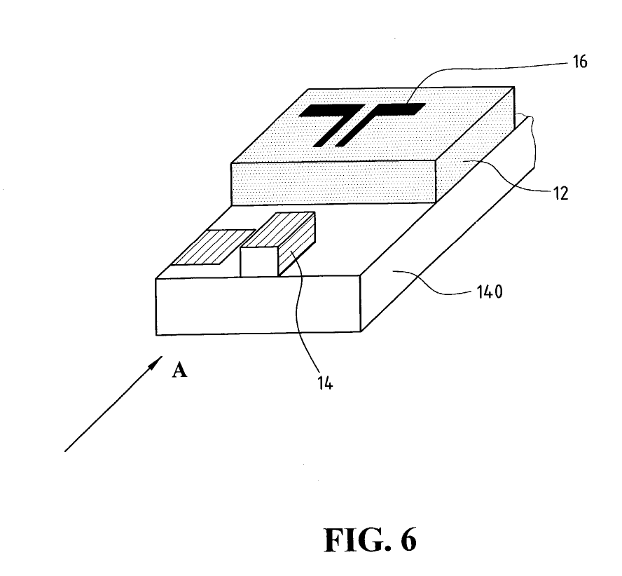

FIG. 6 shows an integrated structure in which the antenna 16 and the photodetector 14 are integrated as a single unit. The antenna 16 is directly formed on a low dielectric constant layer 12 which is then mounted on the semi-insulating substrate 140 of the photodetector 14 to form the single unit. Arrow A indicates incident light. By means of semiconductor manufacturing techniques, the photodetector 14 and the antenna 16 can be integrated as an integrated circuit device.

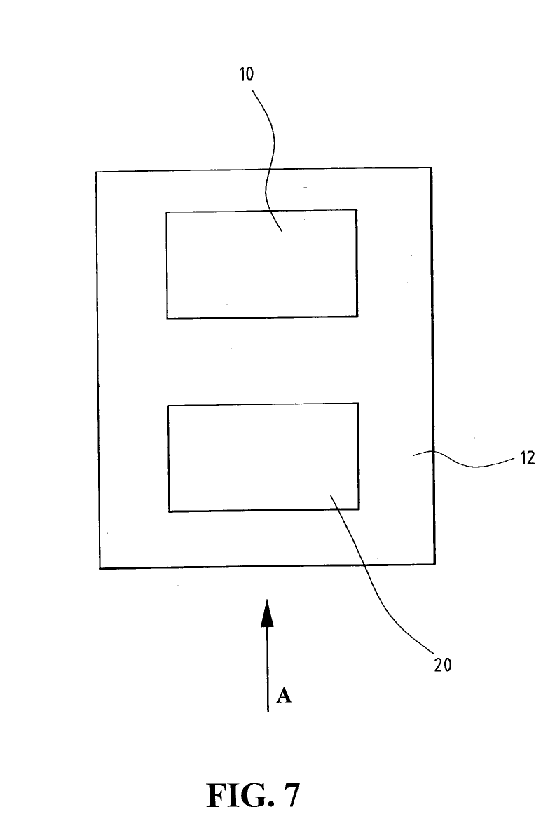

The photodetector 14 that is formed by growing in regular temperature and implanted with impurity atoms can be integrated with other semiconductor devices, such as the example shown in FIG. 7 in which the photonic transmitter 10 of the present invention is formed on a low dielectric constant substrate 12. A semiconductor optical amplifier (SOA) 20 is also formed on the low dielectric constant substrate 12. Thus, the photodetector 10 and the SOA 20 are integrated together as a single unit. The SOA 20 amplifies the incident light as indicated by arrow A and provides an optical signal of acceptable level to the photodetector 10 to generate electromagnetic waves. The provision of the SOA 20 effectively enhances the sensitivity of the device.

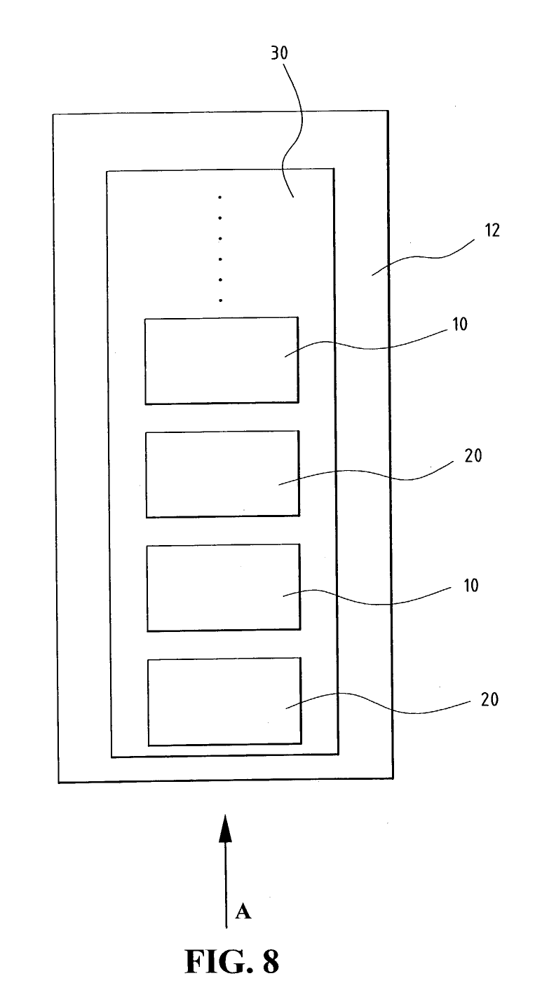

FIG. 8 shows another example in which the photonic transmitter 10 of the present invention is embodied. A number of photonic transmitters 10 constructed in accordance with the present invention are formed on a low dielectric constant substrate 12 with a passive optical waveguide 30 interposed therebetween. An optical amplifier 20 is formed on the passive optical waveguide 30 and corresponds to each photonic transmitter 10. Incident light A is received and transmitted by the passive optical waveguide 30 to each optical amplifier 30 and then to the photonic transmitter 10.

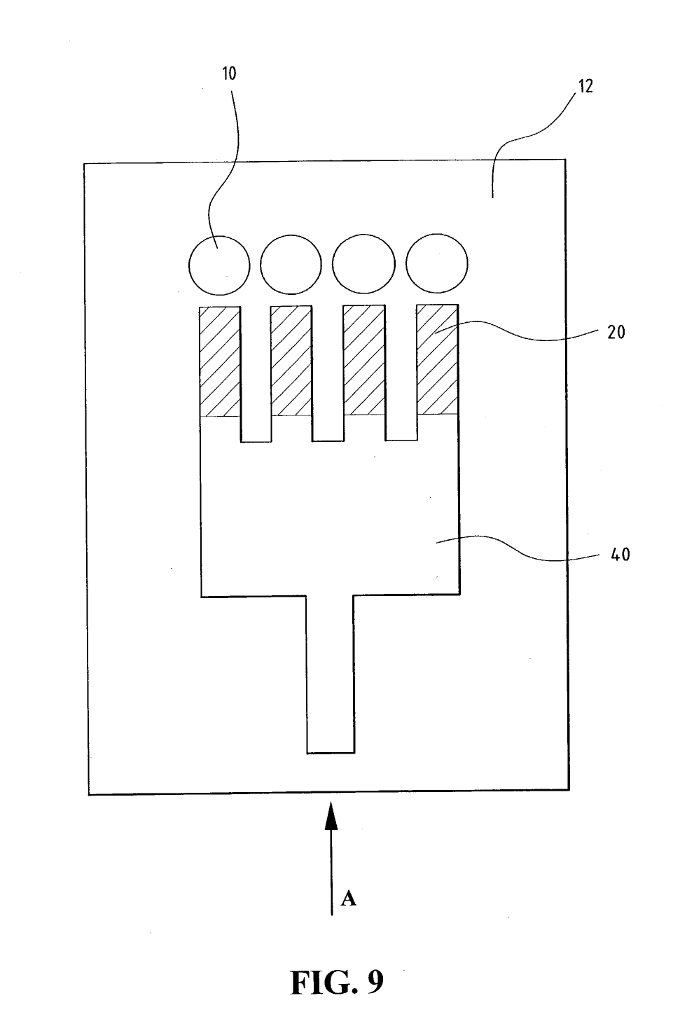

FIG. 9 shows a further example in which the photonic transmitter 10 of the present invention is embodied. A number of photonic transmitters 10 in accordance with the present invention are formed on a low dielectric constant substrate 12. An optical multi-mode interference power splitter 40 is formed on the low dielectric constant substrate 12. The splitter 40 comprises a number of optical amplifiers 20 respectively corresponding to the photonic transmitters 10. Incident light, designated by reference numeral A, is received and guided by the splitter 40 to each optical amplifier 20 which in turn amplifies and transmits the light to the photonic transmitter 10.

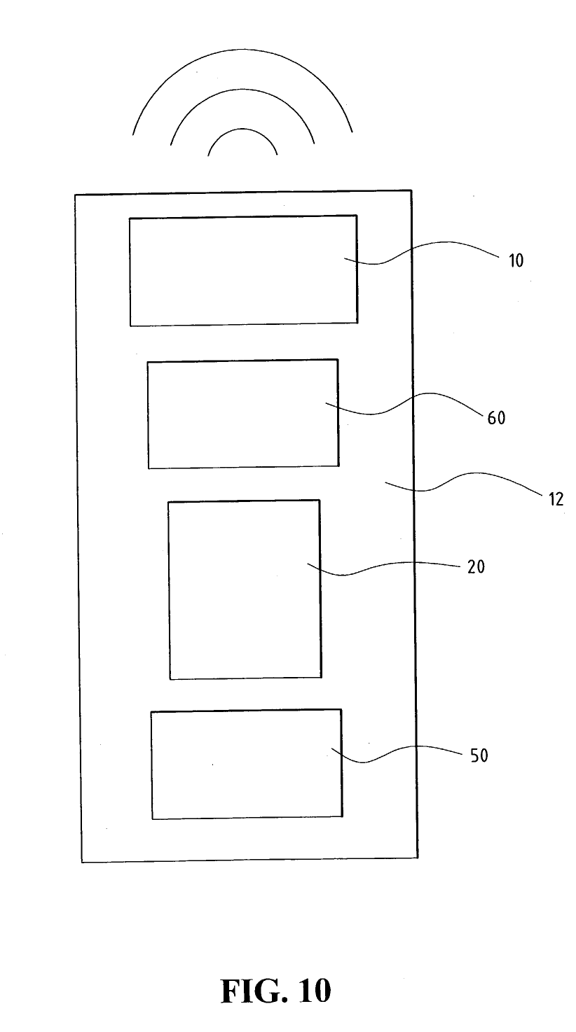

Yet a further example in which the photonic transmitter 10 of the present invention is embodied is shown in FIG. 10, wherein a distributed Bragg grating or an intra-cavity reflector 50 is formed on a low dielectric constant substrate 12. An optical amplifier 20 and phase control 60 are formed on the substrate 12 to increase the gain and phase to a threshold value for lasing. The photonic transmitter 10 also acts as a saturate absorber to mode lock the semiconductor laser The distributed Bragg grating or intra-cavity reflector 50 selects two CW lasing modes that beat each other to increase the repetition rate to the THz range. The optical signal is converted by the photonic transmitter 10 and is then radiated directly. An advantage of this example is that THz ranged waves can be generated without any external optical source. In the example, the distributed Bragg grating or intra-cavity reflector is formed by semiconductor grating which can be integrated with the photonic transmitter 10 as a unitary device. In addition, the phase control device 60 is formed with epitaxy semiconductor layers that can be integrated with the photonic transmitter 10 too.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A photonic transmitter comprising:
a substrate;
an edge-coupled traveling wave photodetector, comprising an active layer formed on the substrate with III-V semiconductor material for absorption photons of external light and having enhanced electrical bandwidth, and an electrode structure formed on the active layer and comprising three metal strips for generating and guiding electromagnetic waves; and
a planar antenna coupled to the electrode structure for transmitting the electromagnetic waves.

2. The photonic transmitter as claimed in claim 1, wherein the planar antenna is monolithically integrated with the photodetector.

3. The photonic transmitter as claimed in claim 1, wherein the substrate comprises a semi-insulating substrate made of III-V semiconductor materials.

4. The photonic transmitter as claimed in claim 3, wherein the III-V semiconductors are selected from a group consisting of GaAs, GaSb and InP.

5. The photonic transmitter as claimed in claim 1, wherein the active layer is made of a material selected from a group consisting of GaAs, InxGa1-xAs, GaAsySb1-y, InAs, and InxGa1-xAsyN1-y that are low temperature grown for shortening carrier life time of the active layer.

6. The photonic transmitter as claimed in claim 1, wherein the active layer is implanted with impurity atoms for shortening carrier life-time of the active layer.

7. The photonic transmitter as claimed in claim 6, wherein the implanted impurity atoms are selected from a group consisting of O⁺, Ni⁺, As⁴⁺, As⁺, N, H, F, Ar, P, B, Ni, Mn, Co and Nd.

8. The photonic transmitter as claimed in claim 1, wherein the substrate comprises a low dielectric constant substrate.

9. The photonic transmitter as claimed in claim 8, wherein the low dielectric constant substrate is made of a material selected from a group consisting of glass, quartz, plastic polymers and silicon carbides.

10. The photonic transmitter as claimed in claim 1, wherein the antenna comprise a coplanar waveguide fed slot antenna.

11. The photonic transmitter as claimed in claim 1 further comprising an impedance matching section between the photodetector and the antenna.

12. The photonic transmitter as claimed in claim 1, wherein the edge-coupled traveling wave photodetector comprises a metal-semiconductor-metal structure and the electrode structure is formed by a self-aligned process as a portion of the metal-semiconductor-metal structure.

13. The photonic transmitter as claimed in claim 1, wherein the edge-coupled traveling wave photodetector comprises a metal-semiconductor-metal structure and the electrode structure is formed by e-beam lithography as a portion of the metal-semiconductor-metal structure.

14. The photonic transmitter as claimed in claim 1, wherein the electrode structure comprises three metal strips comprising at least one grounding strip spaced from each other a gap of 200-300 nm.

15. The photonic transmitter as claimed in claim 12 further comprising an optical isolation layer between the substrate and the active layer for separating the active layer from the substrate.

16. The photonic transmitter as claimed in claim 15 further comprising a cladding layer between the optical isolation layer and the active layer functioning as a waveguide.

17. The photonic transmitter as claimed in claim 12 further comprising a diffusion barrier layer between the substrate and the active layer for preventing out-diffusion of As atoms.

18. The photonic transmitter as claimed in claim 15, wherein the optical isolation layer is made of AlxGa1-xAs.

19. The photonic transmitter as claimed in claim 16, wherein the cladding layer is made of AlxGa1-xAs.

20. The photonic transmitter as claimed in claim 17, wherein the diffusion barrier layer is made of AlAs.

21. The photonic transmitter as claimed in claim 1, wherein the edge-coupled traveling wave photodetector comprises a p⁺-intrinsic-n⁺ structure.

22. The photonic transmitter as claimed in claim 21, wherein the p⁺-intrinsic-n⁺ structure comprises a p-layer formed on the substrate, an i-layer formed on the p-layer and an n-layer formed on the i-layer.

23. The photonic transmitter as claimed in claim 22, wherein the p-layer is made of a p-type material selected from a group consisting of AlxGa1-xAs, InxAl1-xAs, InP, InxGa1-xAsyP1-y.

24. The photonic transmitter as claimed in claim 22, wherein the n-layer is made of an n-type material selected from a group consisting of AlxGa1-xAs, InxAl1-xAs, InP, InxGa1-xAsyP1-y.

25. The photonic transmitter as claimed in claim 22, wherein the i-layer is made of a regular temperature grown material selected from a group consisting of GaAs InxGa1-xAs, InxGa1-xAsyP1-y, GaAsySb1-y, and InxGa1-xAsyN1-y, which are implanted with impurity atoms.

26. The photonic transmitter as claimed in claim 25, wherein the implanted impurity atoms are selected from a group consisting of O⁺, Ni⁺, As⁴⁺, As⁺, N, H, F, Ar, P, B, Ni, Mn, Co and Nd.

27. A photo-electrical system comprising:
a low dielectric constant substrate; and
a photonic transmitter formed on the low dielectric constant substrate and comprising:
an edge-coupled traveling wave photodetector, comprising an active layer made of III-V semiconductor material and an electrode structure formed on the active layer and comprising three metal strips for generating and guiding electromagnetic waves,
a planar antenna coupled to the electrode structure for transmitting the electromagnetic waves, and
an optical amplifier receiving and amplifying an external optical signal and guiding the amplified signal to the photodetector.

28. The photo-electrical system as claimed in claim 27, wherein the planar antenna is monolithically integrated with the photodetector.

29. The photo-electrical system as claimed in claim 27, wherein the active layer is made of a material selected from a group consisting of GaAs, InxGa1-xAs, GaAsySb1-y, InAs, and InxGa1-xAsyN1-y that are low temperature grown for shortening carrier life time of the active layer.

30. The photo-electrical system as claimed in claim 27, wherein the active layer is implanted with impurity atoms for shortening carrier life time of the active layer.

31. The photo-electrical system as claimed in claim 30, wherein the implanted impurity atoms are selected from a group consisting of O⁺, Ni⁺, As⁴⁺, As⁺, N, H, F, Ar, P, B, Ni, Mn, Co and Nd.

32. The photo-electrical system as claimed in claim 27, wherein the low dielectric constant substrate is made of a material selected from a group consisting of glass, quartz, plastic polymers and silicon carbides.

33. The photo-electrical system as claimed in claim 27, wherein the antenna comprise a coplanar waveguide fed slot antenna.

34. The photo-electrical system as claimed in claim 27 further comprising an impedance matching section between the photodetector and the antenna.

35. The photo-electrical system as claimed in claim 27, wherein the edge-coupled traveling wave photodetector comprises a metal-semiconductor-metal structure and the electrode structure is formed by a self-aligned process as a portion of the metal-semiconductor-metal structure.

36. The photo-electrical system as claimed in claim 27, wherein the edge-coupled traveling wave photodetector comprises a metal-semiconductor-metal structure and the electrode structure is formed by e-beam lithography as a portion of the metal-semiconductor-metal structure.

37. The photo-electrical system as claimed in claim 27, wherein the electrode structure comprises three metal strips comprising at least one grounding strip spaced from each other a gap of 200-300 nm.

38. The photo-electrical system as claimed in claim 35 further comprising an optical isolation layer and a cladding layer, the cladding layer being arranged between the optical isolation layer and functioning as a waveguide.

39. The photo-electrical system as claimed in claim 35 further comprising a diffusion barrier layer for preventing out-diffusion of As atoms.

40. The photo-electrical system as claimed in claim 38, wherein the optical isolation layer is made of AlxGa1-xAs.

41. The photo-electrical system as claimed in claim 38, wherein the cladding layer is made of AlxGa1-xAs.

42. The photo-electrical system as claimed in claim 39, wherein the diffusion barrier layer is made of AlAs.

43. The photo-electrical system as claimed in claim 27, wherein the edge-coupled traveling wave photodetector comprises a p⁺-intrinsic-n⁺ structure.

44. The photo-electrical system as claimed in claim 43, wherein the p⁺-intrinsic-n⁺ structure comprises a p-layer formed on the substrate, an i-layer formed on the p-layer and an n-layer formed on the i-layer.

45. The photo-electrical system as claimed in claim 44, wherein the p-layer is made of a p-type material selected from a group consisting of AlxGa1-xAs, InAlAs, InP, InxGa1-xAsyP1-y.

46. The photo-electrical system as claimed in claim 44, wherein the n-layer is made of an n-type material selected from a group consisting of AlxGa1-xAs, InxAl1-xAs, InP, InxGa1-xAsyP1-y.

47. The photo-electrical system as claimed in claim 44, wherein the i-layer is made of a regular temperature grown material selected from a group consisting of GaAs and InxGa1-xAs and implanted with impurity atoms.

48. The photo-electrical system as claimed in claim 47, wherein the implanted impurity atoms are selected from a group consisting of O⁺, Ni⁺, As⁴⁺, As⁺, N, H, F, Ar, P, B, Ni, Mn, Co and Nd.

49. The photo-electrical system as claimed in claim 27 further comprising a passive optical waveguide arranged on the low dielectric constant substrate and below the photodetectors and the optical amplifiers for guiding incident light to the optical amplifier and photodetectors.

50. The photo-electrical system as claimed in claim 49 further comprising a sequence of photodetectors and optical amplifiers. The linear array of photodetectors and optical amplifiers being formed on the passive optical waveguide with the optical amplifiers receiving amplifying light from the passive optical waveguide and guiding the amplified light to the close photodetector.

51. The photo-electrical system as claimed in claim 27 further comprising an optical multi-mode interference power splitter formed on the low dielectric constant substrate to forward incident light to the optical amplifier.

52. The photo-electrical system as claimed in claim 27 further comprising a distributed Bragg grating formed on the low dielectric constant substrate and arranged in front of the optical amplifier.

53. The photo-electrical system as claimed in claim 52, wherein the distributed Bragg grating comprises a semiconductor grating.

54. The photo-electrical system as claimed in claim 52 further comprising a phase control device formed on the low dielectric constant substrate and arranged between the photodetector and the optical amplifier.

55. The photo-electrical system as claimed in claim 54, wherein the phase control device is formed with epitaxy semiconductor layers.

56. The photo-electrical system as claimed in claim 27 further comprising an intra-cavity reflector formed on the low dielectric constant substrate and arranged in front of the optical amplifier.

57. The photo-electrical system as claimed in claim 56, wherein the intra-cavity reflector comprises a semiconductor grating.

58. The photo-electrical system as claimed in claim 56 further comprising a phase control device formed on the low dielectric constant substrate and arranged between the photodetector and the optical amplifier.

59. The photo-electrical system as claimed in claim 58, wherein the phase control device is formed with epitaxy semiconductor layers.
